(19) United States
(12) Patent Application Publication
(10) Pub. No.: US 2013/0210226 A1
(43) Pub. Date: Aug. 15, 2013

(54) PATTERN FORMATION METHOD

(71) Applicant: Yuriko SEINO, Yokohama-shi (JP)

(72) Inventor: Yuriko SEINO, Yokohama-shi (JP)

(21) Appl. No.: 13/592,668

(22) Filed: Aug. 23, 2012

(30) Foreign Application Priority Data
Feb. 10, 2012 (JP) 2012-27078

(51) Int. Cl. H01L 21/28

(52) U.S. Cl. 438/666; 257/E21.158

(57) ABSTRACT

According to one embodiment, a pattern formation method comprises forming a hard mask material on a processed film on a wiring, forming a guide layer on the hard mask material, forming a tetragonal opening in the guide layer, coating the opening with a block polymer, heating the block polymer to form a micro phase separation structure film in which first polymer parts and second polymer parts parallel to the wiring are alternately arranged, removing the second polymer part while leaving the first polymer part, processing the hard mask material with the guide layer and the first polymer part as a mask to form a first hole pattern in the hard mask material, and processing the processed film with the hard mask material as a mask to form a second hole pattern corresponding to the first hole pattern in the processed film.

### CROSS REFERENCE TO RELATED APPLICATION

This application is based upon and claims benefit of priority from the Japanese Patent Application No. 2012-27078, filed on Feb. 10, 2012, the entire contents of which are incorporated herein by reference.

1. Field

Embodiments described herein relate generally to a pattern formation method.

2. Background

Double patterning techniques by ArF liquid immersion exposure, EUV lithography, nanoimprint and the like are known as lithography techniques in processes of producing semiconductor devices. Conventional lithography techniques have various problems such as an increase in costs, a degradation in alignment accuracy and a reduction in throughput in association with miniaturization of patterns.

Under these situations, application of a directed self-assembly (DSA) phenomenon to the lithography technique is expected. A directed self assembly phase is generated by a spontaneous behavior of energy stabilization, and thus can form a pattern with high dimensional accuracy. Particularly, a technique utilizing micro-phase separation in polymer block copolymers can form structures of various shapes of several to several hundred nm by a simple coating and annealing process. Hole, pillar and line patterns of various dimensions can be formed by changing micro-domains into a spherical form, a columnar form, a layered form and the like depending on the composition ratios of blocks of a polymer block copolymer and changing the size depending on the molecular weight.

As a method for forming a hole pattern using DSA, the following method is known. First, a hole pattern of a resist is formed on a processed film by conventional photolithography. Next, a block copolymer is coated on the hole pattern and annealed to thereby form a micro phase separation pattern of a block copolymer along a side wall of a guide (hole pattern). A part of a polymer formed at the center of the hole is selectively removed by applying an oxygen plasma to form a hole pattern having a reduced size in comparison with a hole pattern formed by photolithography.

If a contact hole is formed using the method described above, a hole pattern in the shape of a circle or an ellipse with the longer diameter extending along the wiring direction is formed on a wiring by photolithography. There is a problem that since the wiring pitch equals to the hole pattern pitch, and the wiring pitch is defined by a hole resolution limit of photolithography, a hole pattern for a micro wiring that is no larger than a hole resolution limit cannot be formed.

### BRIEF DESCRIPTION OF THE DRAWINGS

FIG. 1A is a top view for explaining a pattern formation method according to a first embodiment;

FIG. 1B is a sectional view for explaining a pattern formation method according to the first embodiment;

FIG. 2A is a top view subsequent to FIG. 1A;

FIG. 2B is a sectional view subsequent to FIG. 1B;

FIG. 3A is a top view subsequent to FIG. 2A;

FIG. 3B is a sectional view subsequent to FIG. 2B;

FIG. 4A is a top view subsequent to FIG. 3A;

FIG. 4B is a sectional view subsequent to FIG. 3B;

FIG. 5A is a top view subsequent to FIG. 4A;

FIG. 5B is a sectional view subsequent to FIG. 4B;

FIG. 6A is a top view subsequent to FIG. 5A;

FIG. 6B is a sectional view subsequent to FIG. 5B;

FIG. 7A is a top view subsequent to FIG. 6A;

FIG. 7B is a sectional view subsequent to FIG. 6B;

FIG. 8 is a view showing one example of a contact formed by the first embodiment;

FIG. 9A is a top view for explaining a pattern formation method according to a second embodiment;

FIG. 9B is a sectional view for explaining a pattern formation method according to the second embodiment;

FIG. 10A is a top view subsequent to FIG. 9A;

FIG. 10B is a sectional view subsequent to FIG. 9B;

FIG. 11A is a top view subsequent to FIG. 10A;

FIG. 11B is a sectional view subsequent to FIG. 10B;

FIG. 12A is a top view subsequent to FIG. 11A;

FIG. 12B is a sectional view subsequent to FIG. 11B;

FIG. 13A is a top view subsequent to FIG. 12A;

FIG. 13B is a sectional view subsequent to FIG. 12B;

FIG. 14A is a top view subsequent to FIG. 13A;

FIG. 14B is a sectional view subsequent to FIG. 13B;

FIG. 15A is a top view subsequent to FIG. 14A;

FIG. 15B is a sectional view subsequent to FIG. 14B;

FIG. 16A is a top view subsequent to FIG. 15A;

FIG. 16B is a sectional view subsequent to FIG. 15B;

FIG. 17A is a top view subsequent to FIG. 16A;

FIG. 17B is a sectional view subsequent to FIG. 16B; and

FIG. 18 is a view showing one example of a contact formed by the second embodiment.

### DETAILED DESCRIPTION

According to one embodiment, a pattern formation method comprises forming a hard mask material on a processed film on a wiring, forming a guide layer on the hard mask material, forming a tetragonal opening in the guide layer, coating the opening with a block polymer, heating the block polymer to form a micro phase separation structure film in which first polymer parts and second polymer parts parallel to the wiring are alternately arranged, removing the second polymer part while leaving the first polymer part, processing the hard mask material with the guide layer and the first polymer part as a mask to form a first hole pattern in the hard mask material, and processing the processed film with the hard mask material as a mask to form a second hole pattern corresponding to the first hole pattern in the processed film.

Embodiments will now be explained with reference to the accompanying drawings.

### First Embodiment

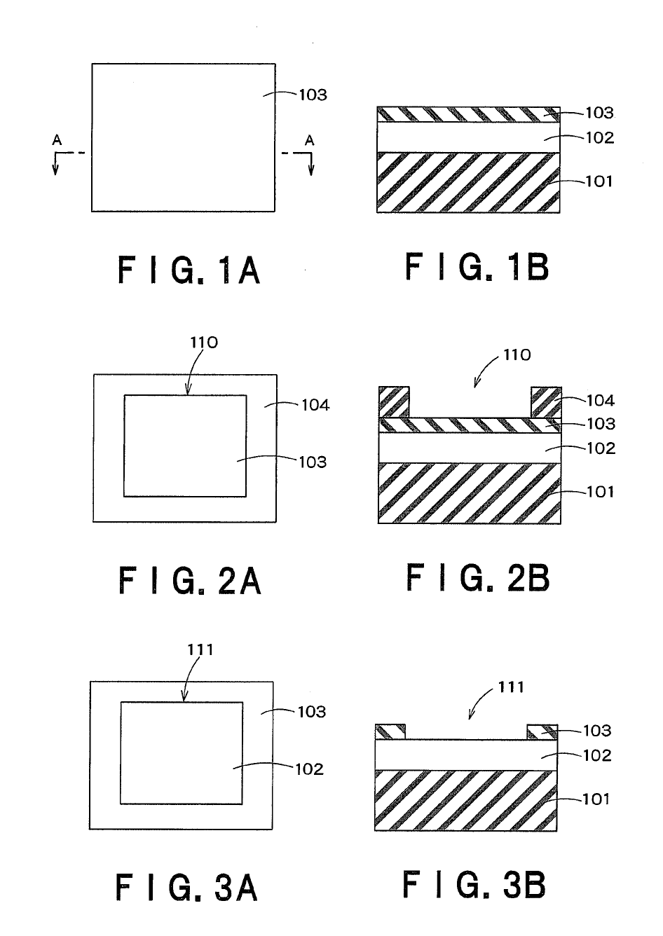

A pattern formation method according to a first embodiment will be described with reference to FIGS. 1 to 7. In each figure, A is a top view of a cell region for forming a contact to a micro wiring, and B is a sectional view of the cell region shown in A. The cross section shown in FIG. 1B corresponds to a cross section taken along line A-A in FIG. 1A, and the same applies to FIGS. 2 to 7.

As shown in FIGS. 1A and 1B, a hard mask material 102 is formed on a processed film 101, and a guide layer 103 is formed on the hard mask material 102. For the processed film 101, an oxide film such as a TEOS film having a thickness of, for example, about 300 nm can be used. On a lower layer of the processed film 101, a plurality of wirings (not shown) are provided side by side along the vertical direction in FIG. 1A.

The hard mask material 102 is intended for transferring to the processed film 101 a micro phase separation pattern of a block polymer to be formed in a post-process. The hard mask material 102 can be formed by, for example, depositing a carbon film having a thickness of about 100 nm by a CVD (chemical vapor deposition) method.

The guide layer 103 serves as a guide for forming a micro phase separation pattern of a block polymer in a post-process. The guide layer 103 can be formed by, for example, depositing a silicon oxide film having a thickness of about 15 nm by a CVD method.

Next, as shown in FIGS. 2A and 2B, a resist 104 is spin-coated, and exposed to light and developed to form a tetragonal (quadrangular) opening 110 in a cell region. The thickness of the resist 104 coated is, for example, 100 nm. In addition, for example, light exposure is carried out in an exposure amount of 20 mJ/cm² by an ArF excimer laser. In the opening 110, the surface of the guide layer 103 is exposed. The shape of the opening 110 is, for example, a tetragon (rectangle) having a width of 76 nm and a length of 75 nm.

A forming region of the opening 110 corresponds to a region for forming a contact to a wiring (not shown) provided on the lower layer of the processed film 101.

Next, as shown in FIGS. 3A and 3B, the guide layer 103 is processed with the resist 104 as a mask to form an opening 111 in the guide layer 103. Processing of the guide layer 103 is carried out by, for example, RIE (reactive Ion etching) using a CF-based gas. In the opening 111, the surface of the hard mask material 102 is exposed. After processing of the guide layer 103, the resist 104 is separated.

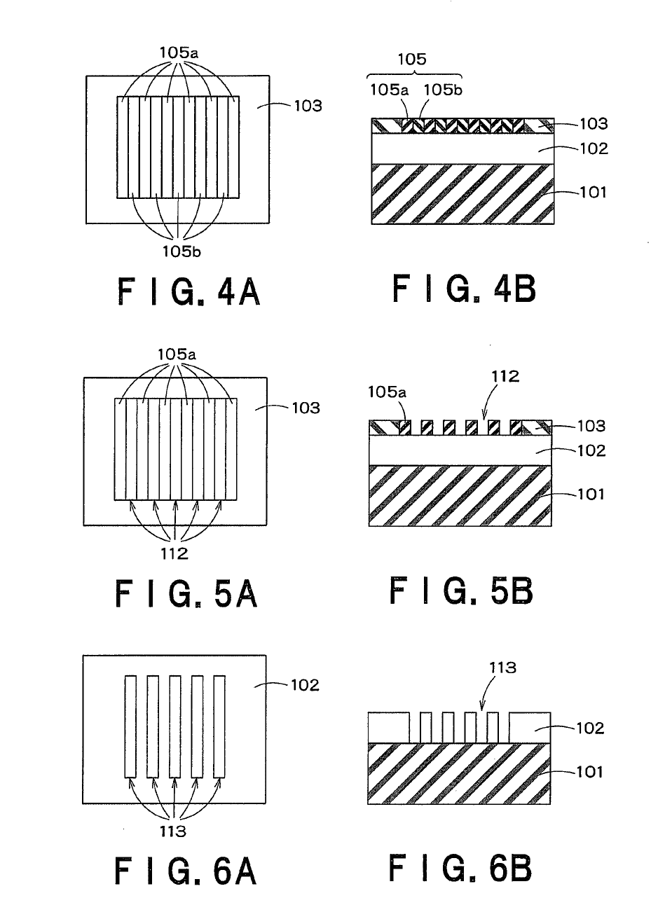

Next, as shown in FIGS. 4A and 4B, the opening 111 is coated with a block copolymer 105 in which first polymer block chains and second polymer block chains are bound. In other words, the opening 111 is filled with the block copolymer 105. Then, the block copolymer 105 is heated to form, by micro phase separation, a thin plate-shaped lamellar micro phase separation structure film in which first polymer parts 105a including first polymer block chains and second polymer parts 105b including second polymer block chains are alternately arranged. The first polymer parts 105a and the second polymer parts 105b are formed in parallel to the wiring (not shown) provided on the lower layer of the processed film 101. The molecular weight and the component ratio of the block copolymer 105 are determined so that one of the first polymer parts 105a and the second polymer parts 105b is located above the wiring on the lower layer of the processed film 101. A portion of the coated block copolymer, which extends off the opening 111, does not undergo even by heating, and is removed.

For the block copolymer 105, for example, a block copolymer of polystyrene (PS) and polydimethylsiloxane (PDMS) can be used. The average molecular weight of the PS block/PDMS block is, for example, 9500/5200. Such a block copolymer is dissolved in polyethylene glycol monomethyl ether acetate (PGMEA) so as to have a concentration of about 1.0 wt %, and the solution is spin-coated at a rotation speed of 2000 rpm. Then, the coated film is baked at 110° C. for 90 seconds to separate the block copolymer into lamellar domains. Since polydimethylsiloxane (PDMS) has a higher affinity for the guide layer 103 than polystyrene (PS) does, domains of polydimethylsiloxane (PDMS) are formed at both ends of a space part 111.

Next, as shown in FIGS. 5A and 5B, etching is carried out under such a condition that the selection ratio of the second polymer part 105b is higher than that of the first polymer part 105a, so that the second polymer part 105b is removed while leaving the first polymer part 105a to form a rectangular (or substantially rectangular) hole pattern 112.

In oxygen RIE, for example, the selection ratio (etching rate) of polystyrene (PS) is higher than that of polydimethylsiloxane (PDMS), so that the domain of polystyrene (PS) can be removed while leaving the domain of polydimethylsiloxane (PDMS) to form a rectangular (or substantially rectangular) hole pattern.

Next, as shown in FIGS. 6A and 6B, the hard mask material 102 is processed by RIE or the like with the guide layer 103 and the first polymer part 105a as a mask. A rectangular or substantially rectangular hole pattern 113 is thereby transferred to the hard mask material 102. Then, the guide layer 103 and the first polymer part 105a are removed.

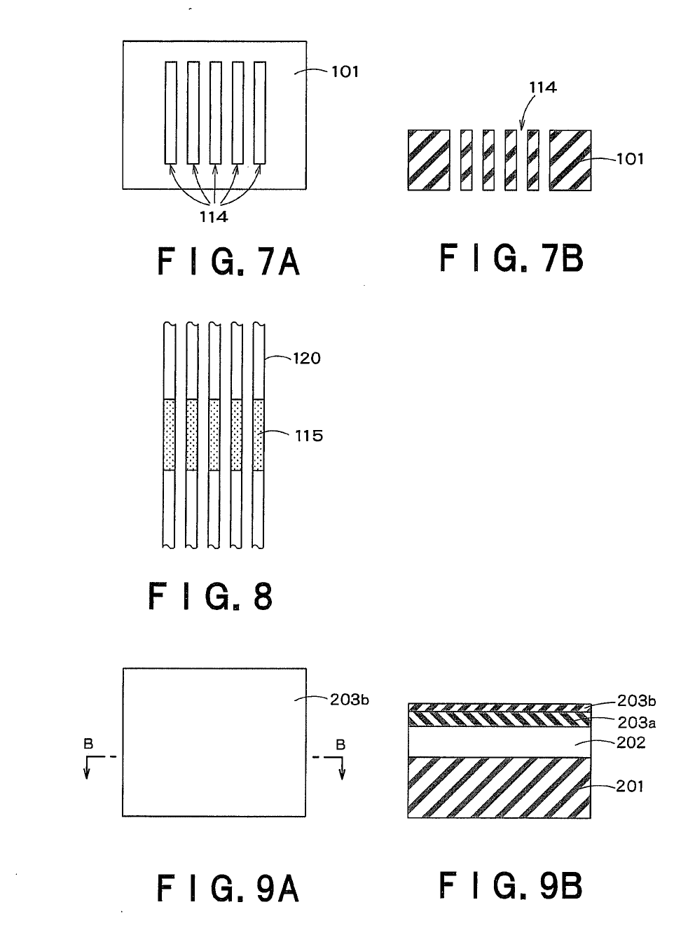

Next, as shown in FIGS. 7A and 7B, the processed film 101 is processed by RIE or the like with the hard mask material 102 as a mask, and the hard mask material 102 is removed by CMP (chemical mechanical polishing) or the like. A rectangular (or substantially rectangular) hole pattern 114 can be thereby transferred to the processed film 101.

By embedding a metal such as tungsten or titanium in the hole pattern 114 thus formed, a plurality of contacts 115 in contact with a plurality of micro wirings 120 arranged side by side at narrow pitches can be formed as shown in FIG. 8. FIG. 8 is a top view, wherein only contacts 115 and wirings 120 are shown and representation of the processed film 101 and the like is omitted. The shape of the cross section of the contact 115 in the lateral direction is substantially a rectangle with the longer side extending along the wiring direction.

In this way, according to this embodiment, a contact to a micro wiring can be formed utilizing micro phase separation of a block polymer. Since photolithography is used for formation of the opening 110 serving as a physical guide, but is not used for formation of micro contact holes, it is not necessary to consider the resolution limit of photolithography. Thus, a contact hole can be formed even for such a micro wiring that the pitch is no larger than the hole resolution limit.

In the embodiment described above, on the space part 111 is formed a lamellar domain in which the first polymer parts 105a and the second polymer parts 105b are alternately arranged, and the second polymer part 105b corresponds to a contact forming region. Thus, it should be noted that an arrangement of the first polymer parts 105a and the second polymer parts 105b is determined from the molecular weight and the component ratio of the block copolymer 105, and the space part 110 is formed by a lithography process so that the second polymer parts 105b are located above the wiring.

### Second Embodiment

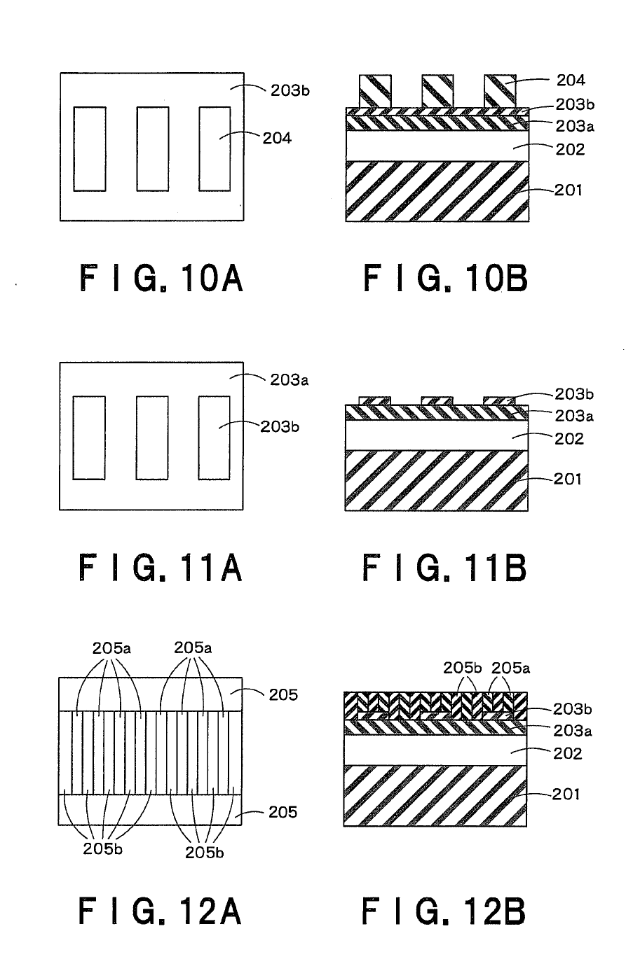

A pattern formation method according to a second embodiment will be described with reference to FIGS. 9 to 17. In each figure, A is a top view of a cell region for forming a contact to a micro wiring, and B is a sectional view of the cell region shown in A. The cross section shown in FIG. 9B corresponds to a cross section taken along line B-B in FIG. 9A, and the same applies to FIGS. 10 to 17.

As shown in FIGS. 9A and 9B, a hard mask material 202 is formed on a processed film 201, and a first guide layer 203a and a second guide layer (neutralization film) 203b are sequentially formed on the hard mask material 202. For the processed film 201, an oxide film such as a TEOS film having a thickness of, for example, about 300 nm can be used. On a lower layer of the processed film 201, a plurality of wirings (not shown) are provided side by side along the vertical direction in FIG. 9A.

The hard mask material 202 is intended for transferring to the processed film 201 a micro phase separation pattern of a block polymer to be formed in a post-process. The hard mask material 202 can be formed by, for example, depositing a carbon film having a thickness of about 100 nm by a CVD (chemical vapor deposition) method.

The first guide layer 203a and the second guide layer 203b serve as a guide for forming a micro phase separation pattern of a block polymer in a post-process. The first guide layer 203a can be formed by, for example, depositing a silicon oxide film having a thickness of about 15 nm by a CVD method. The second guide layer 203b can be formed by, for example, spin-coating at a rotation speed of 2000 rpm a solution prepared by dissolving a random copolymer of polystyrene (PS) and polymethyl methacrylate (PMMA) (PS-r-PMMA) in polyethylene glycol monomethyl ether acetate (PGMEA) in a concentration of 1.0 wt %, and baking the coated film on a hot plate at 110° C. for 90 seconds, and then at 240° C. for 3 minutes.

Next, as shown in FIGS. 10A and 10B, a resist 204 is spin-coated, and exposed to light and developed to form a line-and-space pattern on a cell region. The thickness of the resist 204 coated is, for example, 100 nm. In addition, for example, light exposure is carried out in an exposure amount of 20 mJ/cm² by an ArF excimer laser. The width of a line part of the line-and-space pattern is, for example, about 45 nm. The shape of the line part is rectangular or substantially rectangular.

The pitch of the line-and-space pattern of the resist 204 is determined from the molecular weight and the component ratio of the block copolymer to be used in a post-process, and is an integral multiple (odd multiple) of the pitch of the lamellar micro phase separation pattern of the block copolymer. A region, on which the line-and-space pattern of the resist 204 is formed, includes a region for forming a contact to a wiring (not shown) provided on the lower layer of the processed film 201. The line-and-space pattern is formed in parallel to the wiring (not shown) provided on the lower layer of the processed film 201.

Next, as shown in FIGS. 11A and 11B, the guide layer 203b is processed with the resist 204 as a mask to process the second guide layer 203b into a line-and-space pattern. Processing of the second guide layer 203b is carried out by, for example, oxygen RIE. After the second guide layer 203b is processed, the resist 204 is separated using a thinner or the like.

Next, as shown in FIGS. 12A and 12B, the first guide layer 203a and the second guide layer 203b are coated thereon with a block copolymer 205 in which first polymer block chains and second polymer block chains are bound. Then, the block copolymer 205 is heated to form, by micro phase separation, a thin plate-shaped lamellar micro phase separation structure film in which first polymer parts 205a including first polymer block chains and second polymer parts 205b including second polymer block chains are alternately arranged. The second guide layer 203b serves as so called a chemical guide, lamellar first polymer parts 205a and second polymer parts 205b are arranged in alignment with the second guide layer 203b.

FIGS. 12A and 12B show one example of arrangement of first polymer parts 205a and second polymer parts 205b, wherein the pitch of the line-and-space pattern of the second guide layer 203b is three times as large as the pitch of the micro phase separation pattern of the block copolymer 205. First polymer parts 205a are formed at both ends on the second guide layer 203b (a line part of the line-and-space pattern). Owing to such a characteristic of the lamellar micro phase separation pattern that first polymer parts 205a and second polymer parts 205b are alternately formed, the second polymer part 205b is formed between first polymer parts 205a at both ends on the second guide layer 203b. In a space part of the second guide layer 203b, i.e. on the first guide layer 203a, second polymer parts 205b are formed at both ends, and the first polymer part 205a is formed therebetween.

Since the first polymer parts 205a are formed at both ends on the second guide layer 203b and the first polymer parts 205a and the second polymer parts 205b are alternately formed, the pitch of the line-and-space pattern of the second guide layer 203b is an odd multiple of the pitch of the micro phase separation structure film.

First polymer parts 205a and second polymer parts 205b are formed in parallel to the wiring (not shown) provided on the lower layer of the processed film 201.

As shown in FIG. 12A, on regions which are not provided with the line-and-space pattern of the second guide layer 203b (upper and lower end parts in the figure), no lamellar micro phase separation pattern is formed because there does not exist a chemical guide as a starting point for micro phase separation.

For the block copolymer 205, for example, a block copolymer of polystyrene (PS) and polymethyl methacrylate (PMMA) can be used. The average molecular weight of the PS block/PMMA block is, for example, 21000/21000. Such a block copolymer is dissolved in PGMEA so as to have a concentration of about 1.0 wt %, and the solution is spin-coated at a rotation speed of 2000 rpm. Then, the coated film is baked at 110° C. for 90 seconds and further annealed under a nitrogen atmosphere at 220° C. for 3 minutes, whereby the block copolymer can be separated into lamellar domains having a half pitch of 15 nm (processed into a line-and-space pattern).

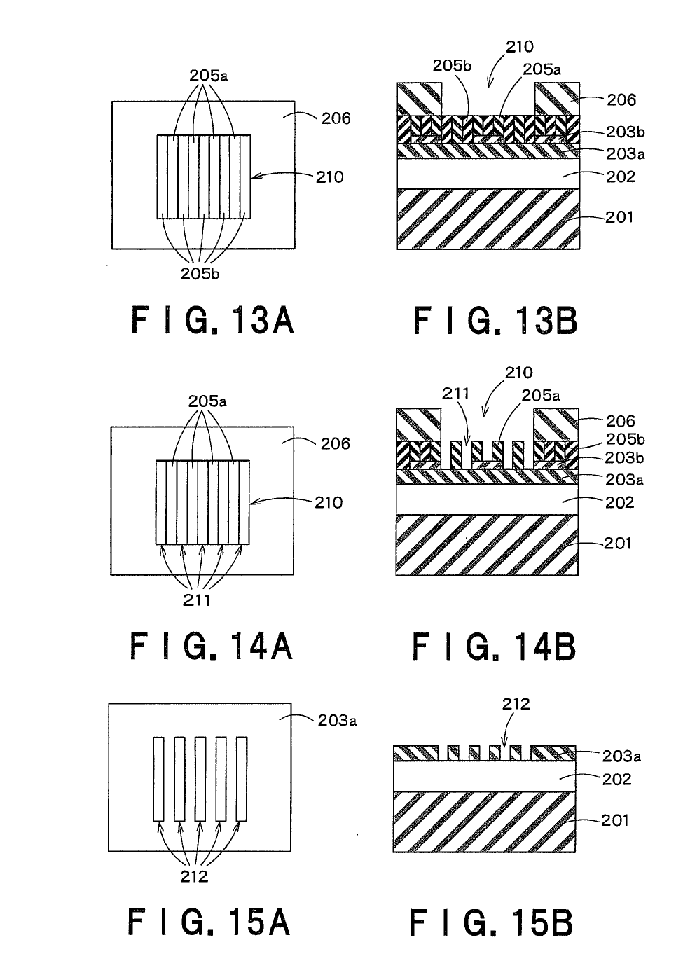

Next, as shown in FIGS. 13A and 13B, a resist 206 is spin-coated on the block copolymer 205, the first polymer part 205a and the second polymer part 205b, and exposed to light and developed to form a tetragonal opening 210 on a cell region. In the opening 210, the surfaces of the first polymer part 205a and the second polymer part 205b are exposed. The shape of the opening 210 is, for example, a tetragon having a width of 76 nm and a length of 75 nm. A forming region of the opening 210 corresponds to a region for forming a contact to a wiring (not shown) provided on the lower layer of the processed film 201.

Next, as shown in FIGS. 14A and 14B, etching is carried out via the opening 210 under such a condition that the selection ratio of the second polymer part 205b is higher than that of the first polymer part 205a, so that the second polymer part 205b is removed while leaving the first polymer part 205a to form a substantially rectangular hole pattern 211.

Next, as shown in FIGS. 15A and 15B, the first guide layer 203a is processed with the first polymer part 205a of the opening 210 as a mask. A substantially rectangular hole pattern 212 is thereby transferred to the first guide layer 203a. Then, the resist 204, the first polymer part 205a, the first polymer part 205a on the lower layer of the resist 204, the second polymer part 205b and the block copolymer 205 are removed. The resist 204 may be removed after the process shown in FIG. 14.

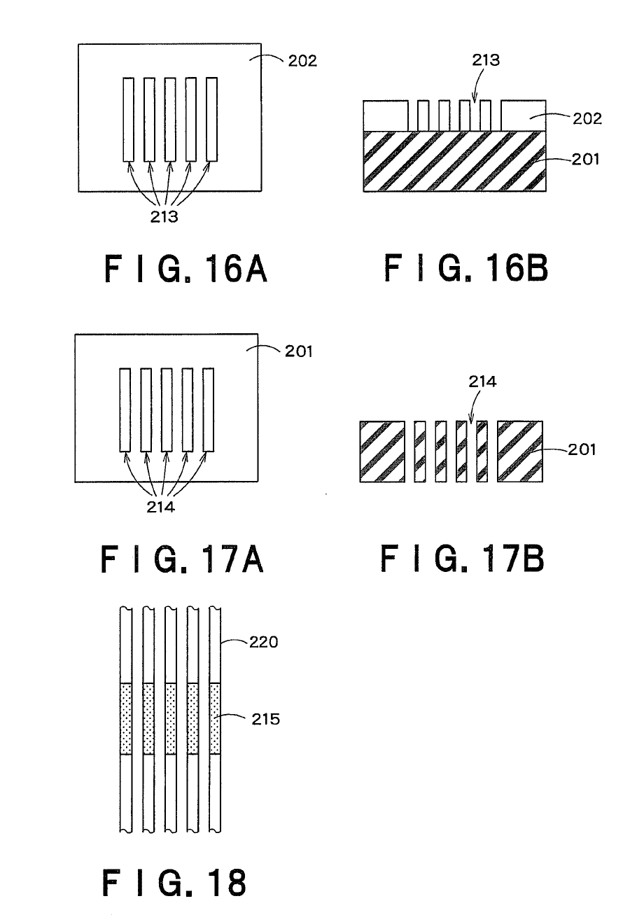

Next, as shown in FIGS. 16A and 16B, the hard mask material 202 is processed by RIE or the like with the first guide layer 203a as a mask. A substantially rectangular hole pattern 213 is thereby transferred to the hard mask material 202. Then, the first guide layer 203a is removed.

Next, as shown in FIGS. 17A and 17B, the processed film 201 is processed by RIE or the like with the hard mask material 202 as a mask, and the hard mask material 202 is removed by CMP (chemical mechanical polishing) or the like. A substantially rectangular hole pattern 214 can be thereby transferred to the processed film 201.

By embedding a metal such as tungsten or titanium in the hole pattern 214 thus formed, a plurality of contacts 215 in contact with a plurality of micro wirings 220 arranged side by side at narrow pitches can be formed as shown in FIG. 18. FIG. 18 is a top view, wherein only contacts 215 and wirings 220 are shown and representation of the processed film 201 and the like is omitted. The shape of the cross section of the contact 215 in the lateral direction is substantially a rectangle with the longer side extending along the wiring direction.

In this way, according to this embodiment, a contact to a micro wiring can be formed utilizing micro phase separation of a block polymer. Since photolithography is used for formation of a chemical guide pattern having a pitch larger than that of the micro phase separation pattern of the block polymer and formation of the opening 210, but is not used for formation of micro contact holes, it is not necessary to consider the resolution limit of photolithography. Thus, a contact hole can be formed even for such a micro wiring that the pitch is no larger than the hole resolution limit.

The first guide layer 203a and the second guide layer (neutralization film) 203b are formed on the hard mask material 202 in the second embodiment, but the first guide layer 203a may be omitted to form the second guide layer (neutralization film) 203a on the hard mask material 202. The process shown in FIGS. 15A and 15B is omitted and the hole pattern 211 is transferred to the hard mask material 202.

PS-b-PDMS and PS-b-PMMA are used as block copolymers in the first and second embodiments, but various kinds of substances such as polybutadiene, polyisoprene, polyethylene oxide and vinyl pyridine can be used for the polymer block. A general resist solvent may be used as a solvent for dissolving the block copolymer.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A pattern formation method comprising:
forming a hard mask material on a processed film on a wiring;
forming a guide layer on the hard mask material;
forming a tetragonal opening in the guide layer;
coating the opening with a block polymer;
heating the block polymer to form a micro phase separation structure film in which first polymer parts and second polymer parts parallel to the wiring are alternately arranged;
removing the second polymer part while leaving the first polymer part;
processing the hard mask material with the guide layer and the first polymer part as a mask to form a first hole pattern in the hard mask material; and
processing the processed film with the hard mask material as a mask to form a second hole pattern corresponding to the first hole pattern in the processed film.

2. The pattern formation method according to claim 1, wherein
the second polymer part is located above the wiring, and
a metal is embedded in the second hole pattern to form a contact in contact with the wiring.

3. The pattern formation method according to claim 2, wherein the shape of the second hole pattern is rectangular or substantially rectangular.

4. The pattern formation method according to claim 1, wherein the opening is formed by a lithography process.

5. A pattern formation method, comprising:
forming a hard mask material on a processed film on a wiring;
forming a neutralization film on the hard mask material;
processing the neutralization film into a line-and-space pattern parallel to the wiring;
coating a block polymer on the hard mask material and the neutralization film after the neutralization film is processed;
heating the block polymer to form a micro phase separation structure film in which the first polymer parts and the second polymer parts parallel to the wiring are alternately arranged;
removing the second polymer part while leaving the first polymer part in a specified region;
processing the hard mask material with the first polymer part as a mask in the specified region to form a first hole pattern in the hard mask material; and
processing the processed film with the hard mask material as a mask to form a second hole pattern corresponding to the first hole pattern in the processed film.

6. The pattern formation method according to claim 5, wherein the pitch of the line-and-space pattern is an odd multiple of the pitch of the first polymer part and the second polymer part.

7. The pattern formation method according to claim 5, wherein
the second polymer part is located above the wiring, and
a metal is embedded in the second hole pattern to form a contact in contact with the wiring.

8. The pattern formation method according to claim 5, wherein the shape of the specified region is tetragonal.

9. The pattern formation method according to claim 5, wherein the shape of the second hole pattern is rectangular or substantially rectangular.

10. The pattern formation method according to claim 5, comprising:
forming an oxide film between the hard mask material and the neutralization film,
processing the oxide film with the first polymer part as a mask in the specified region; and
processing the hard mask material with the processed oxide film as a mask to form the first hole pattern.

11. The pattern formation method according to claim 10, wherein the pitch of the line-and-space pattern is an odd multiple of the pitch of the first polymer part and the second polymer part.

12. The pattern formation method according to claim 10, wherein
the second polymer part is located above the wiring, and
a metal is embedded in the second hole pattern to form a contact in contact with the wiring.

13. The pattern formation method according to claim 10, wherein the shape of the specified region is tetragonal.

14. The pattern formation method according to claim 10, wherein the shape of the second hole pattern is rectangular or substantially rectangular.
